(19) United States
(12) Patent Application Publication
(10) Pub. No.: US 2024/0379706 A1
(43) Pub. Date: Nov. 14, 2024

(54) IMAGE PICKUP ELEMENT AND ELECTRONIC DEVICE

(71) Applicant: SONY SEMICONDUCTOR SOLUTIONS CORPORATION, KANAGAWA (JP)

(72) Inventor: MASANORI TANAKA, KANAGAWA (JP)

(21) Appl. No.: 18/578,324

(22) PCT Filed: Mar. 24, 2022
(86) PCT No.: PCT/JP2022/014065

§ 371 Date: Jan. 11, 2024

(30) Foreign Application Priority Data
Aug. 4, 2021 (JP) 2021-128386

(51) Int. Cl. H01L 27/146; H04N 25/11

(52) U.S. Cl. CPC H01L 27/14627; H01L 27/14621; H01L 27/14623; H01L 27/14643; H04N 25/11

(57) ABSTRACT

An image pickup element according to an embodiment of the present disclosure includes a pixel portion (3) in which a plurality of pixels (2) is arrayed in a matrix, in which the plurality of pixels (2) each includes a plurality of photoelectric conversion elements (21) arranged in a planar direction of the pixel portion (3), a first lens (23) that is an example of an optical member positioned on a light incident side with respect to the plurality of photoelectric conversion elements (21) and refracting light, and a second lens (25) positioned on the light incident side with respect to the first lens (23), the first lens (23) of a first pixel among the plurality of pixels (2) is arranged to be shifted in the planar direction by a first shift amount with respect to the plurality of photoelectric conversion elements (21) of the first pixel, and the first lens (23) of a second pixel different from the first pixel among the plurality of pixels (2) is arranged to be shifted in the planar direction by a second shift amount different from the first shift amount with respect to the plurality of photoelectric conversion elements (21) of the second pixel.

### FIELD

The present disclosure relates to an image pickup element and an electronic device.

### BACKGROUND

As means for obtaining a parallax signal in an image pickup element such as an image sensor, there are a light shielding film method in which a Si surface opening of a pixel is half shielded by a light shielding film, and a PD division method in which a plurality of photodiodes (PDs) is provided under one microlens. In an image pickup element for an interchangeable lens camera, a light shielding film system is adopted to deal with various lens pupil distances, and the light shielding width of the light shielding film is adjusted to deal with various lens pupil distances. However, the sensitivity is lowered by shielding light. On the other hand, the PD division method has good sensitivity because there is no light shielding film, but it is difficult to deal with various lens pupil distances as in the light shielding film method.

A pixel structure in which a plurality of PDs form one unit pixel can acquire both imaging information and parallax information, and is attracting attention. At this time, it is required to deal with various pupil distances in a high image height region away from the pixel array optical axis. For example, in Patent Literature 1, the positions of isolation bands among the plurality of PDs included in the unit pixel are made different according to the image height, and a plurality of patterns for making the positions different is provided, thereby realizing coping with various pupil distances.

### CITATION LIST

### Patent Literature

Patent Literature 1: JP 2019-41178 A

### SUMMARY

### Technical Problem

However, in the method of adjusting the position of the isolation bands described above, since the areas and dimensions of the plurality of PDs are different in the entire pixel array, the PDs are not regularly arrayed, and adverse effects on imaging characteristics such as variations in individual pixel characteristics and color mixture occur, and the pixel characteristics are deteriorated.

Therefore, the present disclosure proposes an image pickup element and an electronic device capable of coping with various pupil distances while suppressing deterioration in pixel characteristics.

### Solution to Problem

An image pickup element, according to the embodiment of the present disclosure includes: a pixel portion in which a plurality of pixels is arrayed in a matrix, wherein the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member, the optical member of a first pixel among the plurality of pixels is arranged to be shifted in the planar direction by a first shift amount with respect to the plurality of photoelectric conversion elements of the first pixel, and the optical member of a second pixel different from the first pixel among the plurality of pixels is arranged to be shifted in the planar direction by a second shift amount different from the first shift amount with respect to the plurality of photoelectric conversion elements of the second pixel.

An electronic device, according to the embodiment of the present disclosure includes: an image pickup element, wherein the image pickup element includes a pixel portion in which a plurality of pixels is arrayed in a matrix, the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member, the optical member of a first pixel among the plurality of pixels is arranged to be shifted in the planar direction by a first shift amount with respect to the plurality of photoelectric conversion elements of the first pixel, and the optical member of a second pixel different from the first pixel among the plurality of pixels is arranged to be shifted in the planar direction by a second shift amount different from the first shift amount with respect to the plurality of photoelectric conversion elements of the second pixel.

### BRIEF DESCRIPTION OF DRAWINGS

FIG. 1 is a diagram depicting an example of a schematic configuration of an image pickup element according to a first embodiment.

FIG. 2 is a diagram depicting an example of a stacked structure of a pixel portion according to the first embodiment.

FIG. 3 is a diagram depicting an example of a schematic configuration of a pixel according to the first embodiment.

FIG. 4 is a diagram depicting an example of a schematic configuration of a pixel according to the first embodiment.

FIG. 5 is a diagram depicting an example of a schematic configuration of a pixel according to the first embodiment.

FIG. 6 is a diagram for explaining operation advantages of the short pupil pixel and the long pupil pixel according to the first embodiment.

FIG. 7 is a diagram depicting an example of a schematic configuration of a pixel portion according to Modification 1.

FIG. 8 is a diagram depicting an example of a schematic configuration of a pixel according to Modification 1.

FIG. 9 is a diagram depicting an example of a schematic configuration of a pixel according to Modification 1.

FIG. 10 is a diagram depicting an example of a schematic configuration of a pixel according to Modification 1.

FIG. 11 is a diagram depicting an example of a schematic configuration of a pixel portion according to Modification 2.

FIG. 12 is a diagram for explaining operation advantages of the short pupil pixel and the long pupil pixel according to Modification 2.

FIG. 13 is a diagram depicting an example of a schematic configuration of a pixel portion according to Modification 3.

FIG. 14 is a diagram depicting an example of a schematic configuration of a pixel according to Modification 3.

FIG. 15 is a diagram depicting an example of a schematic configuration of a pixel according to a second embodiment.

FIG. 16 is a diagram depicting an example of a schematic configuration of a pixel according to the second embodiment.

FIG. 17 is a diagram depicting an example of a schematic configuration of a pixel according to the second embodiment.

FIG. 18 is a block diagram depicting an example of schematic configuration of an imaging apparatus.

FIG. 19 is a block diagram depicting an example of schematic configuration of a vehicle control system.

FIG. 20 is a diagram of assistance in explaining an example of installation positions of an outside-vehicle information detecting section and an imaging section.

FIG. 21 is a view depicting an example of a schematic configuration of an endoscopic surgery system.

FIG. 22 is a block diagram depicting an example of a functional configuration of a camera head and a camera control unit (CCU).

### DESCRIPTION OF EMBODIMENTS

Hereinafter, embodiments of the present disclosure will be described in detail with reference to the drawings. The apparatus (including elements), the method, the system, and the like according to the present disclosure are not limited by the embodiments. In addition, in the following one or a plurality of embodiments (examples and modifications), basically the same parts are denoted by the same reference numerals, and redundant description is omitted.

Note that each of the following one or the plurality of embodiments (examples and modifications) can be implemented independently. On the other hand, each of the following embodiments may be implemented at least partially in appropriate combination with at least some of other embodiments. These embodiments may include novel features that are different from one another. Therefore, the embodiments can contribute to solving different objects or problems, and can exhibit different effects.

The present disclosure will be described according to the following order of items.
1. First Embodiment
1-1. Example of Schematic Configuration of Image Pickup Element
1-2. Example of Schematic Configuration of Pixel Portion
1-3. Example of Schematic Configuration of Pixel
1-4. Modification of Pixel Portion
1-4-1. Modification 1
1-4-2. Modification 2
1-4-3. Modification 3
1-5. Operation Advantage
2. Second Embodiment
2-1. Example of Schematic Configuration of Pixel
2-2. Operation Advantage
3. Other Embodiments
4. Usage Example
5. Application Example
5-1. Application Example to Mobile Body
5-2. Application Example to Endoscopic Surgery System
6. Appendix

### 1. First Embodiment

### <1-1. Example of Schematic Configuration of Image Pickup Element>

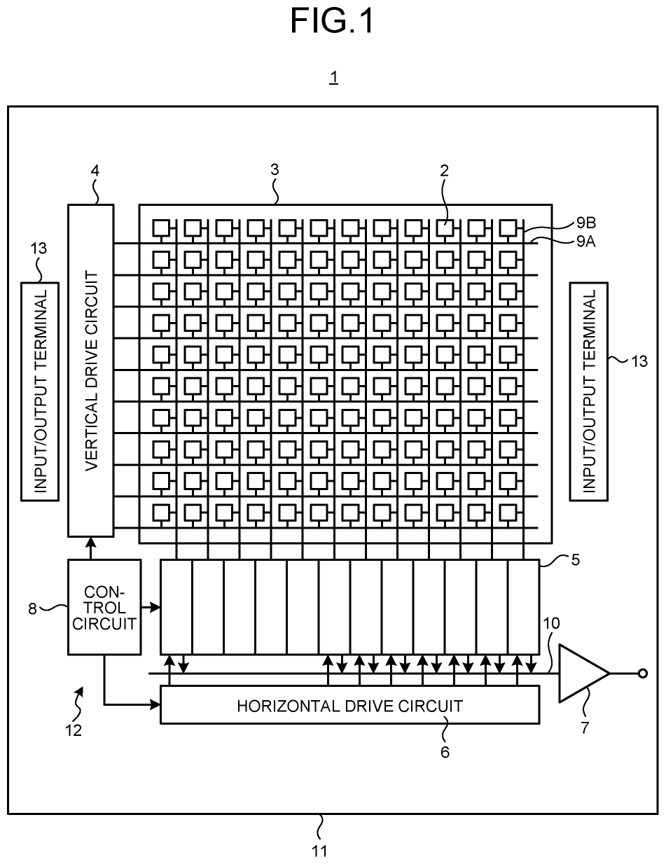

An example of a schematic configuration of an image pickup element 1 according to the present embodiment will be described with reference to FIG. 1. FIG. 1 is a diagram depicting an example of a schematic configuration of the image pickup element 1 according to the present embodiment. The image pickup element 1 according to the present embodiment is, for example, a solid-state image pickup element such as a CMOS image pickup element.

As illustrated in FIG. 1, the image pickup element 1 according to the present embodiment includes, for example, a semiconductor substrate 11 such as a silicon substrate. The semiconductor substrate 11 includes a pixel portion 3 having a plurality of pixels (unit pixels) 2 and a peripheral circuit unit 12 located around the pixel portion 3. The pixel portion 3 includes a pixel region in which the pixels 2 are two-dimensionally arrayed in a matrix on the semiconductor substrate 11, that is, an imaging region.

The pixels 2 include, for example, a plurality of photoelectric conversion elements such as photodiodes and a plurality of pixel transistors (so-called MOS transistors). Each pixel transistor includes, for example, three transistors of a transfer transistor, a reset transistor, and an amplification transistor. In addition, a selection transistor may be added to configure a pixel transistor with four transistors. Since an equivalent circuit of the pixels 2 is similar to a normal case, a detailed description thereof will be omitted. The pixels 2 may have a shared pixel structure. This pixel sharing structure includes a plurality of photodiodes, a plurality of transfer transistors, one shared floating diffusion, and each one of other shared pixel transistors.

The peripheral circuit unit 12 includes a vertical drive circuit 4, column signal processing circuits 5, a horizontal drive circuit 6, an output circuit 7, and a control circuit 8.

The control circuit 8 receives an input clock and data instructing an operation mode and the like, and outputs data such as internal information of the image pickup element. That is, the control circuit 8 generates a clock signal or a control signal serving as a reference of operations of the vertical drive circuit 4, the column signal processing circuits 5, the horizontal drive circuit 6, and the like on the basis of the vertical synchronization signal, the horizontal synchronization signal, and the master clock. Then, the control circuit 8 inputs these signals to the vertical drive circuit 4, the column signal processing circuits 5, the horizontal drive circuit 6, and the like.

The vertical drive circuit 4 includes, for example, a shift register, selects a pixel drive line 9A, supplies a pulse for driving the pixels 2 to the selected pixel drive line 9A, and drives the pixels 2 in units of rows. That is, the vertical drive circuit 4 sequentially selects and scans each of the pixels 2 of the pixel portion 3 in the vertical direction in units of rows, and supplies a pixel signal based on a signal charge generated according to the amount of received light in the photoelectric conversion element of each of the pixels 2 to the column signal processing circuits 5 through the vertical signal line 9B.

For example, the column signal processing circuit 5 is arranged for each column of the pixels 2, and performs signal processing such as noise removal on the signals output from the pixels 2 of one row for each pixel column. That is, the column signal processing circuits 5 performs signal processing such as CDS for removing fixed pattern noise unique to the pixels 2, signal amplification, and AD conversion. In the output stage of the column signal processing circuits 5, a horizontal selection switch (not illustrated) is connected and provided between the column signal processing circuit and a horizontal signal line 10.

The horizontal drive circuit 6 includes, for example, a shift register, sequentially selects each of the column signal processing circuits 5 by sequentially outputting horizontal scanning pulses, and causes each of the column signal processing circuits 5 to output a pixel signal to the horizontal signal line 10.

The output circuit 7 performs signal processing on the signals sequentially supplied from each of the column signal processing circuits 5 through the horizontal signal line 10, and outputs the processed signals. As the signal processing, for example, only buffering may be performed, or black level adjustment, column variation correction, various digital signal processing, and the like may be performed. An input/output terminal 13 exchanges signals externally.

### <1-2. Example of Schematic Configuration of Pixel Portion>

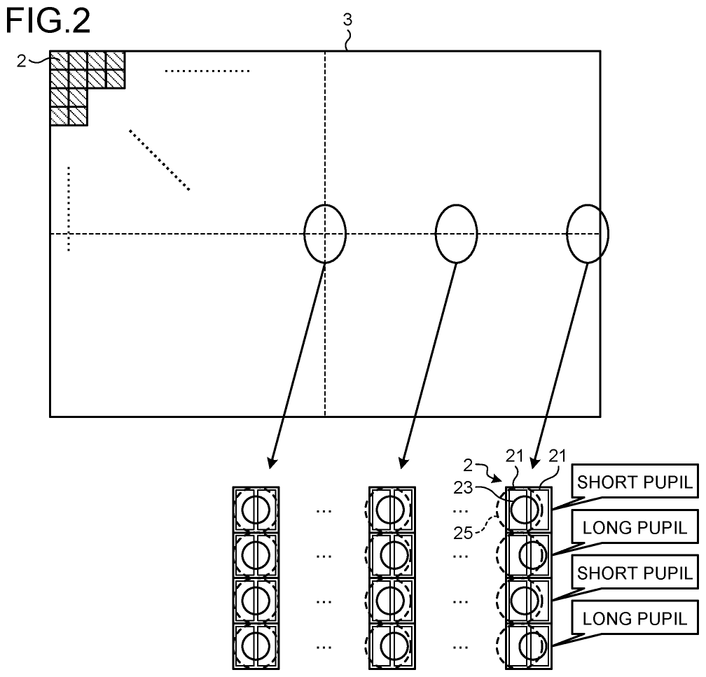

An example of a schematic configuration of the pixel portion 3 according to the present embodiment will be described with reference to FIG. 2. FIG. 2 is a diagram depicting an example of a schematic configuration of the pixel portion 3 according to the present embodiment.

As illustrated in FIG. 2, the pixel portion 3 includes a plurality of pixels 2. These pixels 2 are provided in a matrix (matrix form). Each of the pixels 2 includes a plurality of short pupil pixels and a plurality of long pupil pixels. Note that the short pupil pixels and the long pupil pixels are alternately provided in the row direction. For example, the short pupil pixels are provided in odd-numbered rows, and the long pupil pixels are provided in even-numbered rows. The short pupil pixels and the long pupil pixels enable coping with various pupil distances (lens pupil distances) in a high image height region away from the optical axis (pixel array optical axis) of the pixel portion 3. The short pupil pixel corresponds to a first pixel, and the long pupil pixel corresponds to a second pixel.

### <1-3. Example of Schematic Configuration of Pixel>

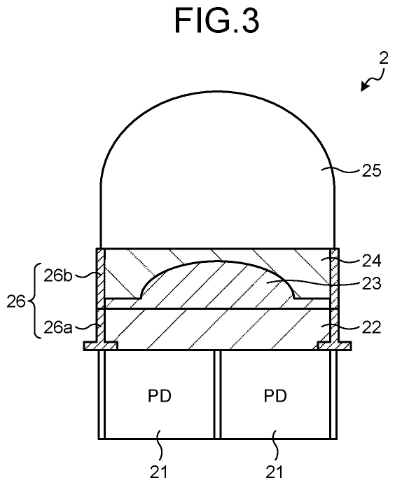

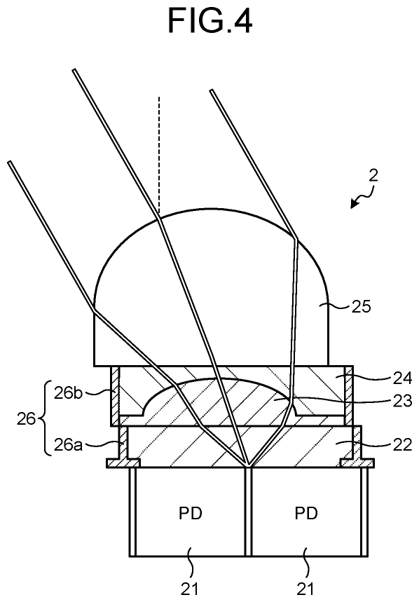

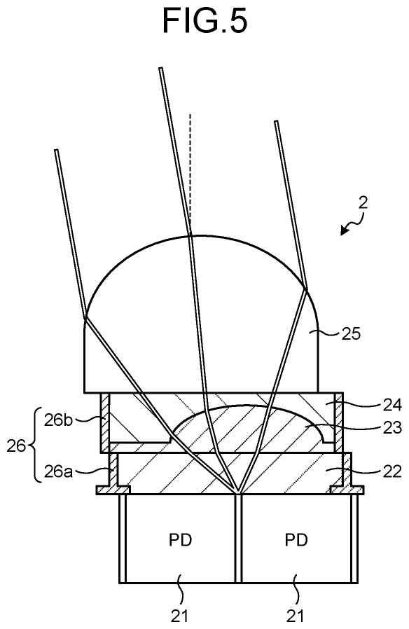

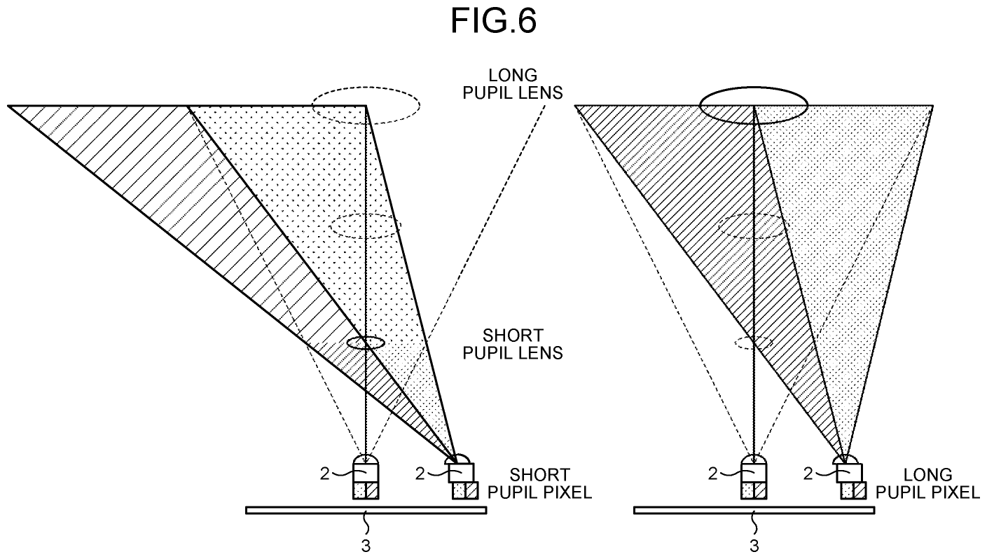

An example of a schematic configuration of the pixels 2 according to the present embodiment will be described with reference to FIGS. 3 to 6. FIGS. 3 to 5 are diagrams each depicting an example of a schematic configuration of the pixels 2 according to the present embodiment. Specifically, FIG. 3 is a diagram depicting an example of a schematic configuration of a center pixel, FIG. 4 is a diagram depicting an example of a schematic configuration of a short pupil pixel, and FIG. 5 is a diagram depicting an example of a schematic configuration of a long pupil pixel. FIG. 6 is a diagram for explaining operation advantages of the short pupil pixel and the long pupil pixel according to the present embodiment.

Here, the basic configuration of the center pixel (pixel near the center of the pixel portion 3) is the same as the basic configuration of each of the short pupil pixel and the long pupil pixel. Therefore, a basic configuration will be described with reference to FIG. 3, and a configuration (shift structure) different from that in FIG. 3 will be described with reference to FIGS. 4 and 5.

As illustrated in FIG. 3, the pixels 2 include a plurality of photoelectric conversion elements 21, an insulating layer 22, a first lens 23, a flattening layer 24, a second lens 25, and a light shielding wall 26. As described above, the plurality of pixels 2 is provided in the pixel portion 3 in a matrix. These pixels 2 are partitioned by the light shielding wall 26. The first lens 23 corresponds to an optical member.

Each photoelectric conversion element 21 is an element that photoelectrically converts incident light and generates a photocurrent from the incident light. As the photoelectric conversion element 21, for example, a photodiode (PD) is used. For example, two photoelectric conversion elements 21 are provided. At this time, the pixel 2 has a substantially square shape in plan view, and each of the pair of photoelectric conversion elements 21 has a substantially rectangular shape in plan view.

The insulating layer 22 is provided on each photoelectric conversion element 21. The insulating layer 22 may be formed of a plurality of layer films having translucency. For example, the insulating layer 22 may include an antireflection film.

The first lens 23 is positioned with respect to each photoelectric conversion element 21 and is provided on the insulating layer 22. The first lens 23 is disposed in a layer constituting the pixels 2 and functions as an inner lens. The first lens 23 is configured to be, for example, a convex lens. In addition, the first lens 23 is formed of, for example, a nitride film.

The flattening layer 24 is provided on the first lens 23. The flattening layer 24 is a layer having translucency and is a layer that forms a flat layer for installation of the second lens 25. The flattening layer 24 is formed of, for example, an organic material such as resin.

The second lens 25 is provided on the flattening layer 24 and functions as an on-chip microlens. The second lens 25 is configured to be, for example, a convex lens. In addition, the second lens 25 is formed of, for example, an organic material such as resin.

Note that the second lens 25 and the first lens 23 are, for example, the same convex lens, but their shapes may be different or the same. In addition, each size of the second lens 25 and the first lens 23 may be different from each other or may be the same. In the example of FIG. 3, the size of the second lens 25 is larger than the size of the first lens 23.

The light shielding wall 26 is a wall (pixel separation unit) that separates and partitions each of the pixels 2. The light shielding wall 26 includes a first light shielding wall 26a and a second light shielding wall 26b. The first light shielding wall 26a is provided in the insulating layer 22, and the second light shielding wall 26b is provided in the flattening layer 24. The light shielding wall 26 has, for example, a lattice shape as viewed from the light incident surface (upper surface in FIG. 3) of the pixel 2. The light shielding wall 26 is formed of, for example, a metal material.

Here, the pixel 2 is a back-illuminated type, and light enters from the back surface (upper surface in FIG. 3) side of the pixel 2, is condensed by the second lens 25 and the first lens 23, and is received by each photoelectric conversion element 21. Note that a wiring layer (not illustrated) including various transistors such as pixel transistors and various wirings is provided on the front surface (lower surface in FIG. 3) side of the pixel portion 3. The wiring layer may be formed of, for example, a plurality of layers. Since the wiring layer side is not the light incident side, the layout of the transistor and the wiring can be freely set.

According to the pixel 2 having such a configuration, since the light shielding wall 26, which is a light-shielding region, is formed at the pixel boundary close to the back surface (the upper surface in FIG. 3), which is the light incident surface, light that cannot be condensed by the second lens 25 and is directed toward the adjacent pixel side is shielded. That is, the light shielding wall 26 at the pixel boundary can suppress light incident on an adjacent pixel, and optical color mixture can be reduced. In addition, since the first lens 23 is formed in the layer between each photoelectric conversion element 21 and the second lens 25, the light condensing efficiency to each photoelectric conversion element 21 is further improved. As a result, it is possible to further reduce the optical color mixture to the adjacent pixel.

Note that the pair of photoelectric conversion elements 21 absorbs light incident through the second lens 25 and the first lens 23 to generate charges. The phase difference can be detected by detecting a difference between the pixel signals based on the charges generated by the pair of photoelectric conversion elements 21. Specifically, the amount of electric charge generated, that is, the sensitivity of the photoelectric conversion elements 21 changes depending on the incident angle of light with respect to its own optical axis (axis perpendicular to its own light receiving surface). For example, the photoelectric conversion element 21 has the highest sensitivity when the incident angle is 0 degrees, and further, the sensitivity of the photoelectric conversion elements 21 has a line-symmetric relationship with respect to the incident angle with the incident angle being 0 degrees as the object axis. Therefore, in the pair of photoelectric conversion elements 21, light from the same point is incident at different incident angles, and charges of amounts corresponding to the incident angles are generated, so that a shift (phase difference) occurs in the detected image. That is, the phase difference can be detected by detecting a difference between the pixel signals based on the charge amount generated by the pair of photoelectric conversion elements 21.

Here, as illustrated in FIG. 3, the first lens 23 and the second lens 25 are not shifted in the planar direction with respect to the center (for example, the central axis of the pixel 2) in the planar direction of the pair of photoelectric conversion elements 21, but as illustrated in FIG. 4, in the short pupil pixel, the first lens 23 and the second lens 25 are shifted in the planar direction with respect to the center in the planar direction of the pair of photoelectric conversion elements 21. Furthermore, as illustrated in FIG. 5, also in the long pupil pixel, the first lens 23 and the second lens 25 are shifted in the planar direction with respect to the center in the planar direction of the pair of photoelectric conversion elements 21.

In any of the pixels 2 illustrated in FIGS. 3 to 5, the first lens 23 and the second lens 25 are shifted such that a light condensing point is located at the center of the pair of photoelectric conversion elements 21 in the planar direction. For example, the shift amount increases as it is positioned outside the pixel portion 3. The cross point angle can be controlled by adjusting the shift amount.

As illustrated in FIG. 4, in the short pupil pixel, the first lens 23 is arranged to be shifted in the planar direction, that is, in a first shift direction, by the first shift amount with respect to the center in the planar direction of the pair of photoelectric conversion elements 21. The first shift amount is a shift amount corresponding to a distance between first lens 23 and the optical axis (pixel array optical axis) of pixel portion 3. The first shift direction is a direction toward the inside of the pixel portion 3 in the planar direction (see FIG. 2). Note that, in the short pupil pixel, the second lens 25 is arranged to be shifted in the first shift direction by a predetermined shift amount with respect to the center in the planar direction of the pair of photoelectric conversion elements 21.

As illustrated in FIG. 5, in the long pupil pixel, the first lens 23 is arranged to be shifted in the planar direction, that is, in a second shift direction, by the second shift amount with respect to the center in the planar direction of the pair of photoelectric conversion elements 21. The second shift amount is a shift amount corresponding to the distance between first lens 23 and the optical axis (pixel array optical axis) of pixel portion 3. The second shift amount is a numerical value different from the first shift amount, and is, for example, a numerical value larger than the first shift amount. The second shift direction is a direction toward the outside of the pixel portion 3 in the planar direction (see FIG. 2). Note that, in the long pupil pixel, the second lens 25 is arranged to be shifted in the first shift direction by a predetermined shift amount with respect to the center in the planar direction of the pair of photoelectric conversion elements 21.

As illustrated in FIG. 6, the short pupil pixel can receive light by dividing the pupil of the short pupil lens into right and left. Furthermore, the long pupil pixel can receive light by dividing the pupil of the long pupil lens into right and left. As a result, it is possible to deal with various pupil distances by adjusting the shift amount without changing the area and dimension of the pair of photoelectric conversion elements 21, and thus, it is possible to deal with various pupil distances while suppressing deterioration in pixel characteristics.

### <1-4. Modification of Pixel Portion>

### <1-4-1. Modification 1>

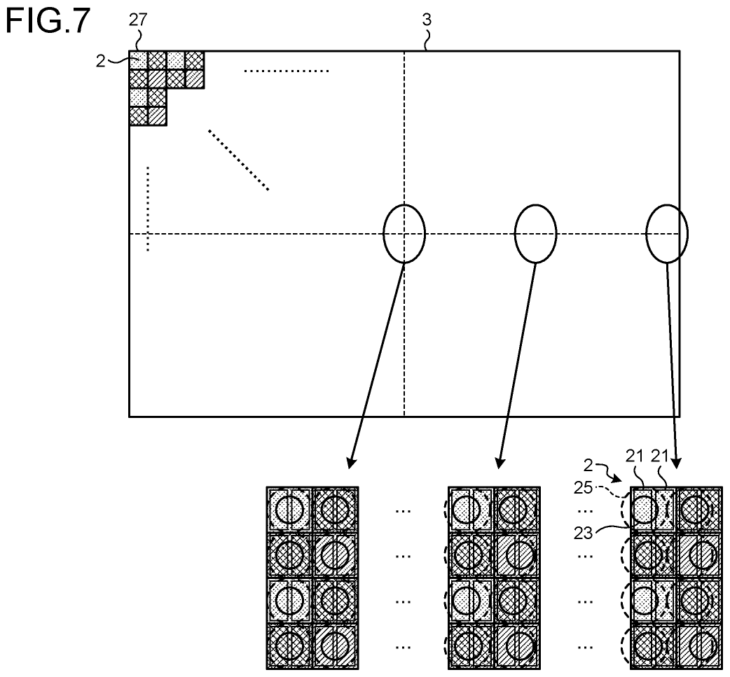

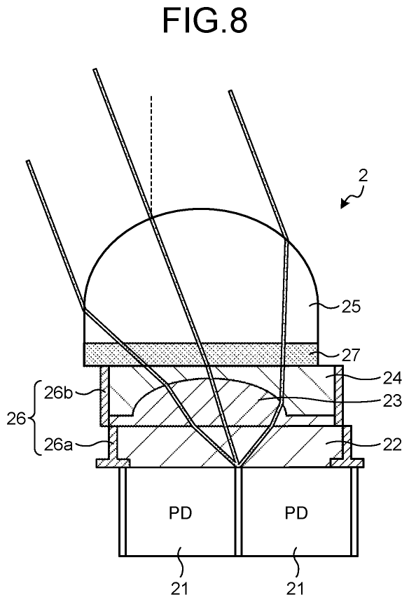

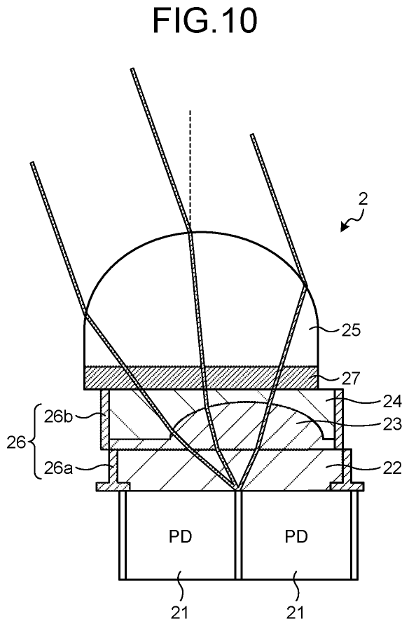

Modification 1 of the pixel portion 3 according to the present embodiment will be described with reference to FIGS. 7 to 10. FIG. 7 is a diagram depicting an example of a schematic configuration of the pixel portion 3 according to Modification 1. FIGS. 8 to 10 are diagrams each depicting an example of a schematic configuration of the pixels 2 according to Modification 1.

As illustrated in FIG. 7, the pixel portion 3 according to Modification 1 includes a color filter 27 for each pixel 2. For example, a Bayer array is used as the array of the color filters 27. In the example of FIG. 7, the Bayer array of 1×1 pixels is used as the Bayer array, but the Bayer array is not limited thereto, and a Bayer array of 2×2 pixels or 4×4 pixels may be used. As the array of the color filters 27, an array other than the Bayer array may be used.

As illustrated in FIGS. 8 to 10, the color filter 27 is provided between the flattening layer 24 and the second lens 25. The color filter 27 functions as an on-chip color filter. The color filter 27 is any of a color filter that transmits a red wavelength component, a color filter that transmits a green wavelength component, and a color filter that transmits a blue wavelength component. For example, the color filter 27 may be formed of a material in which a pigment or a dye is dispersed in a transparent binder.

The shift amount by which the first lens 23 is shifted differs for each color of the color filters 27. That is, the shift amount of each of the short pupil pixel and the long pupil pixel (for example, the first shift amount or the second shift amount) differs according to the color of the color filters 27. Here, since the refractive index has wavelength dependency, the light condensing point changes for each color of the color filters 27. This light condensing point can be corrected by adjusting the shift amount.

Note that, in the pixel 2 illustrated in FIGS. 8 to 10, light is incident from the back surface (the upper surface in FIGS. 8 to 10) side of the pixel 2, is condensed by the second lens 25, and passes through the color filters 27. Then, the light having passed through the color filters 27 is further condensed by the first lens 23 and received by each photoelectric conversion element 21.

### <1-4-2. Modification 2>

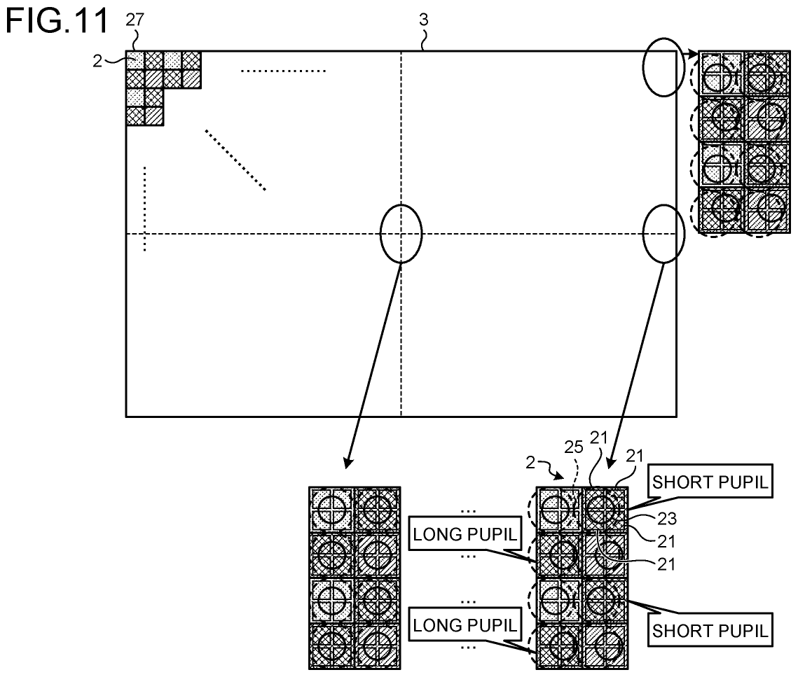

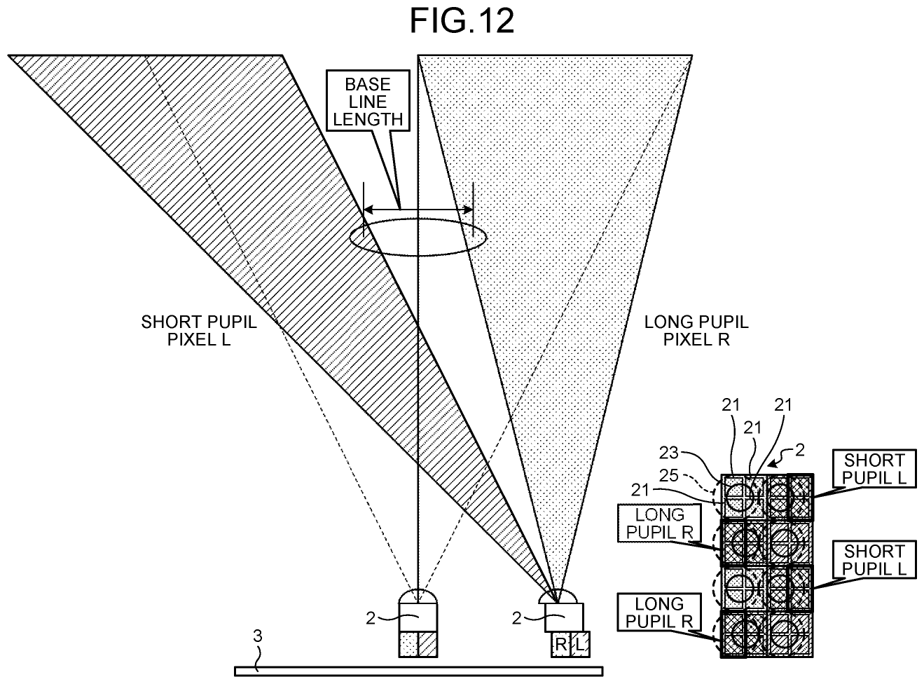

Modification 2 of the pixel portion 3 according to the present embodiment will be described with reference to FIGS. 11 and 12. FIG. 11 is a diagram depicting an example of a schematic configuration of the pixel portion 3 according to Modification 2. FIG. 12 is a diagram for explaining operation advantages of the short pupil pixel and the long pupil pixel according to Modification 2.

As illustrated in FIG. 11, in the pixel portion 3 according to Modification 2, the pixel 2 includes not a pair of photoelectric conversion elements 21 but four photoelectric conversion elements 21. That is, the pixels 2 are not divided into two, but are divided into four. In the example of FIG. 11, each of the short pupil pixel and the long pupil pixel includes a color filter 27 of the same color (for example, green). A plurality of the short pupil pixels and a plurality of the long pupil pixels are alternately arranged in the row direction and the column direction.

As illustrated in FIG. 12, the pupil resolution can be improved by comparing the individual signals of the short pupil pixel and the long pupil pixel in which the color filters 27 have the same color. For example, a parallax signal having a long base line length can be acquired depending on the pupil distance, and AF (autofocus) accuracy can be improved in a large-diameter lens. Furthermore, various corrections (for example, flare/reflected light removal, lens aberration correction, and the like), image processing (for example, refocusing or the like), and the like can be performed on the basis of information obtained by performing comparison processing, difference processing, and the like on the individual signals of the short pupil pixels and the long pupil pixels in which the color filters 27 have the same color.

### <1-4-3. Modification 3>

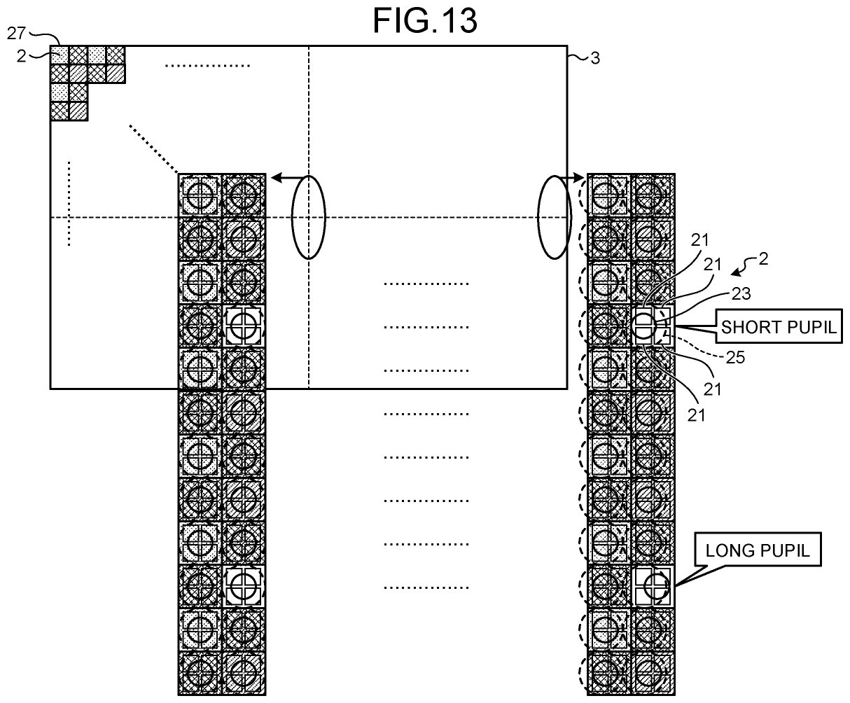

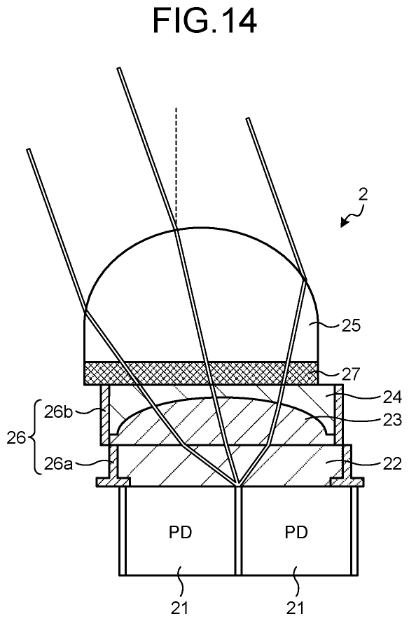

Modification 3 of the pixel portion 3 according to the present embodiment will be described with reference to FIGS. 13 and 14. FIG. 13 is a diagram depicting an example of a schematic configuration of the pixel portion 3 according to Modification 3. FIG. 14 is a diagram depicting an example of a schematic configuration of a pixel 2 according to Modification 3, and specifically, is a diagram depicting an example of a schematic configuration of a normal pixel.

As illustrated in FIG. 13, in the pixel portion 3 according to Modification 3, the short pupil pixel and the long pupil pixel in each pixel 2 are provided at predetermined specific positions. Each of the short pupil pixel and the long pupil pixel is a parallax pixel (for example, a pixel for generating a parallax signal) that prioritizes generation of a parallax signal, and the normal pixel is an imaging pixel (for example, a pixel for generating an imaging signal) that prioritizes generation of an imaging signal. In the example of FIG. 13, the short pupil pixels and the long pupil pixels are arranged in the row direction, but the present invention is not limited thereto. For example, the short pupil pixels and the long pupil pixels may be arranged in the column direction, or may be arranged in a cross shape. That is, the array pattern of the short pupil pixels and the long pupil pixels is not particularly limited.

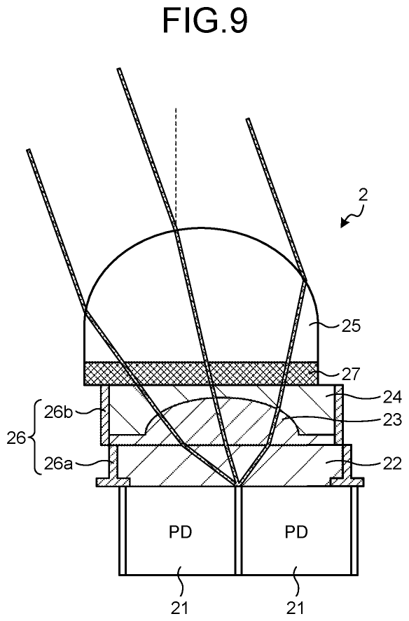

As illustrated in FIG. 14, in the pixel 2 which is a normal pixel, the size of the first lens 23 is larger than the size of the first lens 23 (see FIG. 9 and the like) which is a short pupil pixel or a long pupil pixel. As a result, oblique incidence characteristics of the normal pixel can be improved. Note that each size of the first lens 23 of the normal pixel and the first lens 23 of the short pupil pixel or the long pupil pixel may be different from each other or may be the same. In addition, the shapes of the first lens 23 of the normal pixel and the first lens 23 of the short pupil pixel or the long pupil pixel may be different from each other or may be the same.

### <1-5. Operation Advantage>

As described above, according to the first embodiment, the image pickup element 1 includes the pixel portion 3 in which the plurality of pixels 2 is arrayed in a matrix, and each pixel 2 includes the plurality of photoelectric conversion elements 21 arranged in the planar direction of the pixel portion 3, the first lens 23 which is an example of an optical member positioned on the light incident side with respect to each photoelectric conversion element 21 and refracting light, and the second lens 25 positioned on the light incident side with respect to the first lens 23. Then, the first lens 23 of the first pixel of the pixels 2 is arranged to be shifted in the planar direction by the first shift amount with respect to each photoelectric conversion element 21 of the first pixel, and the first lens 23 of the second pixel different from the first pixel of the pixels 2 is arranged to be shifted in the planar direction by the second shift amount different from the first shift amount with respect to each photoelectric conversion element 21 of the second pixel. As a result, it is possible to deal with various pupil distances by adjusting the shift amount without changing the area and dimension of the plurality of photoelectric conversion elements 21, and thus, it is possible to deal with various pupil distances while suppressing deterioration in pixel characteristics.

In addition, the first lens 23 may be an inner lens. As a result, it is possible to easily deal with various pupil distances by adjusting the shift amount of the first lens 23.

In addition, the shape of the first lens 23 and the shape of the second lens 25 may be different. As a result, it is possible to perform light condensing adjustment by combining lenses having different shapes, and thus, it is possible to improve the efficiency of light condensing to each photoelectric conversion element 21. Therefore, it is possible to reduce the optical color mixture to the adjacent pixel.

In addition, the size of the first lens 23 and the size of the second lens 25 may be different. As a result, it is possible to perform light condensing adjustment by combining lenses having different size, and thus, it is possible to improve the efficiency of light condensing to each photoelectric conversion element 21. Therefore, it is possible to reduce the optical color mixture to the adjacent pixel.

Furthermore, the first shift amount may be a shift amount corresponding to the distance between the first lens 23 of the first pixel and the optical axis (pixel array optical axis) of the pixel portion 3, and the second shift amount may be a shift amount corresponding to the distance between the first lens 23 of the second pixel and the optical axis of the pixel portion 3. As a result, the short pupil pixel and the long pupil pixel can be reliably obtained.

Furthermore, the first shift direction of the first lens 23 of the first pixel and the second shift direction of the first lens 23 of the second pixel may be different. As a result, the short pupil pixel and the long pupil pixel can be more reliably obtained.

Furthermore, the first shift direction may be a direction toward the inside of the pixel portion 3 in the planar direction of the pixel portion 3, and the second shift direction may be a direction toward the outside of the pixel portion 3 in the planar direction of the pixel portion 3. As a result, the short pupil pixel and the long pupil pixel can be more reliably obtained.

Furthermore, a plurality of first pixels and a plurality of second pixels may be provided, and the first pixels and the second pixels may be alternately arranged. As a result, an array pattern in which the short pupil pixels and the long pupil pixels are alternately arranged can be obtained.

In addition, the first pixels and the second pixels may be alternately arranged in the row direction. As a result, an array pattern in which the short pupil pixels and the long pupil pixels are alternately arranged in the row direction can be obtained.

In addition, the first pixels and the second pixels may be alternately arranged in the row direction and in the column direction. As a result, an array pattern in which the short pupil pixels and the long pupil pixels are alternately arranged in the row direction and in the column direction can be obtained.

Furthermore, a plurality of first pixels and a plurality of second pixels may be provided, and the first pixels and the second pixels may be arranged at predetermined specific positions. As a result, an array pattern in which the short pupil pixels and the long pupil pixels are present at predetermined specific positions.

In addition, the first pixels and the second pixels may include the color filters 27 of different colors that transmit light of different wavelength bands, and the first shift amount and the second shift amount may be different according to the color filters 27 of different colors. As a result, it is possible to correct the light condensing point shift due to the wavelength dependency of the refractive index.

Furthermore, the first pixels and the second pixels may have the color filters 27 of the same color that transmit light of the same wavelength band. Thus, the pupil resolution can be improved by comparing the signals of the short pupil pixel and the long pupil pixel in which the color filters 27 have the same color.

Furthermore, the pixel portion 3 may include, as the plurality of pixels 2, an imaging pixel prioritizing generation of an imaging signal and a parallax pixel prioritizing generation of a parallax signal, and the first pixels and the second pixels may be parallax pixels. As a result, the incident angle characteristics of each of the imaging pixel and the parallax pixel can be optimized independently.

In addition, the shape of the first lens 23 of the imaging pixel and the shape of the first lens 23 of the parallax pixel may be different. As a result, the incident angle characteristics of each of the imaging pixel and the parallax pixel can be improved or optimized.

In addition, the size of the first lens 23 of the imaging pixel and the size of the first lens 23 of the parallax pixel may be different. As a result, the incident angle characteristics of each of the imaging pixel and the parallax pixel can be improved or optimized.

In addition, the size of the first lens 23 of the imaging pixel may be larger than the size of the first lens 23 of the parallax pixel. As a result, for example, the incident angle characteristics of the imaging pixel can be improved.

### 2. Second Embodiment

### <2-1. Example of Schematic Configuration of Pixel>

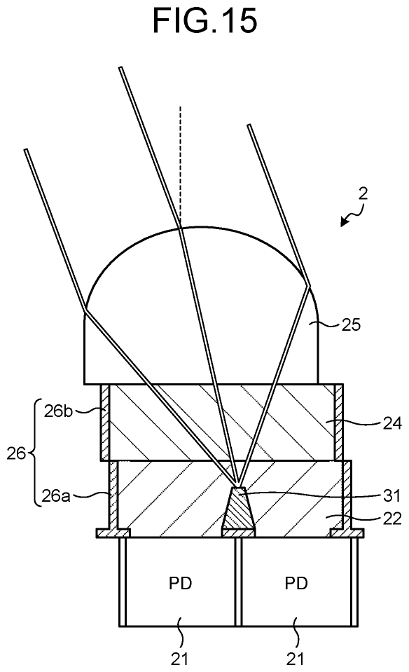

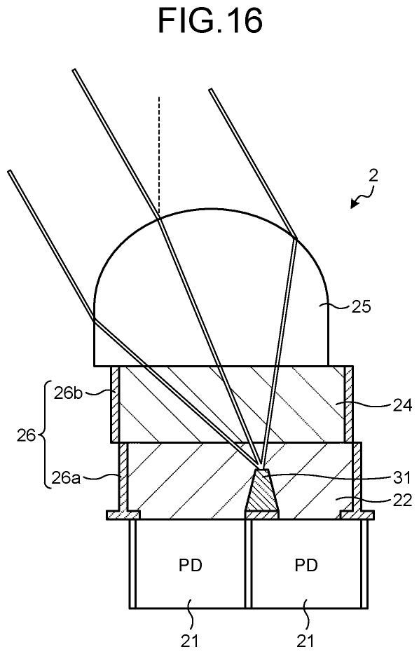

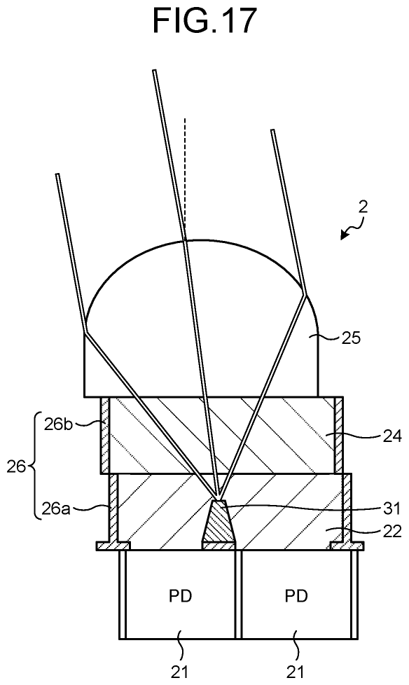

An example of a schematic configuration of pixels 2 according to the present embodiment will be described with reference to FIGS. 15 to 17. FIGS. 15 to 17 are diagrams each depicting an example of a schematic configuration of the pixels 2 according to the present embodiment. Specifically, FIG. 15 is a diagram depicting an example of a schematic configuration of a normal pixel, FIG. 16 is a diagram depicting an example of a schematic configuration of a short pupil pixel, and FIG. 17 is a diagram depicting an example of a schematic configuration of a long pupil pixel. Hereinafter, differences from the first embodiment will be mainly described, and other descriptions will be omitted.

As illustrated in FIGS. 15 to 17, the pixels 2 according to the present embodiment include a light shielding unit 31 instead of the first lens 23 according to the first embodiment. The light shielding unit 31 corresponds to an optical member.

The light shielding unit 31 is positioned with respect to a pair of photoelectric conversion elements 21 and is provided on an insulating layer 22. The light shielding unit 31 is a wall having a shape (protruding shape) extending toward the light incident side, and refracts and shields the light incident on the pixels 2. Furthermore, the light shielding unit 31 is formed to extend along a boundary (extending direction of the boundary) of the pair of photoelectric conversion elements 21 in the planar direction. The light shielding unit 31 is formed of, for example, a metal material having a refractive index lower than that of the insulating layer 22.

Furthermore, similarly to the first lens 23 according to the first embodiment, for example, the light shielding unit 31 is shifted in a direction parallel to the center in the planar direction of the pair of photoelectric conversion elements 21. Note that the shift amount of the light shielding unit 31 is different among the normal pixel, the short pupil pixel, and the long pupil pixel. Furthermore, the normal pixel, the short pupil pixel, and the long pupil pixel may have different shift directions.

### <2-2. Operation Advantage>

As described above, according to the second embodiment, the same effects as those of the first embodiment can be obtained. That is, in the second embodiment, since the light shielding unit 31 is provided instead of the first lens 23 according to the first embodiment, it is possible to obtain the same effect as each effect according to the first embodiment.

Furthermore, the light shielding unit 31, which is an example of the optical member, may be a light shielding unit having a shape extending toward the light incident side. As a result, it is possible to easily deal with various pupil distances by adjusting the shift amount of the light shielding unit 31.

Furthermore, the light shielding unit 31 is formed to extend along a boundary of the photoelectric conversion elements 21 in the planar direction. As a result, it is possible to easily and reliably deal with various pupil distances by adjusting the shift amount of the light shielding unit 31.

### 3. Other Embodiments

The above-described embodiments (or modifications) may be implemented in various different modes (modifications) other than the above-described embodiments. For example, among the processing described in the embodiments, all or a part of the processing, described as automatic processing, can be performed manually, or all or a part of the processing, described as manual processing, can be performed automatically by a known method. In addition, the processing procedures, specific names, and information including various data and parameters indicated in the document and the drawings can be arbitrarily changed unless otherwise specified. For example, various types of information illustrated in the drawings are not limited to the illustrated information.

Furthermore, the constituent elements of the individual devices illustrated in the drawings are functionally conceptual and are not necessarily configured physically as illustrated in the drawings. To be specific, the specific form of distribution and integration of the devices is not limited to the one illustrated in the drawings, and all or a part thereof can be configured by functionally or physically distributing and integrating in arbitrary units according to various loads, usage conditions, and the like.

Furthermore, the above-described embodiments (or modifications) can be appropriately combined within a range that the processing contents do not contradict each other. In addition, the effects described in the present specification are merely examples and are not limited, and other effects may be provided.

### 4. Usage Example

Furthermore, the image pickup element 1 as described above can be applied to various electronic devices such as an imaging apparatus (imaging system) such as a digital still camera or a digital video camera, a mobile phone having an imaging function, or another device having an imaging function, for example.

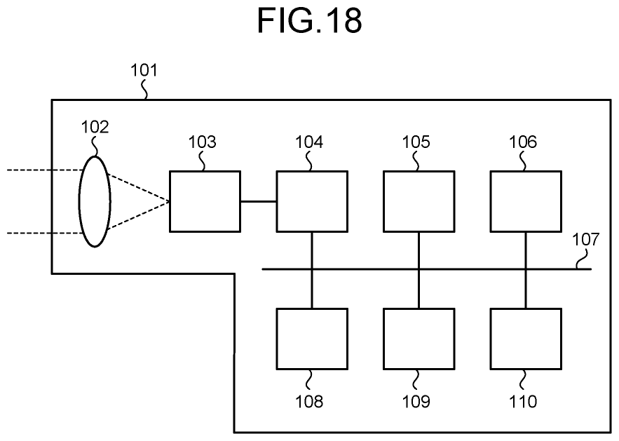

FIG. 18 is a block diagram depicting a configuration example of an imaging apparatus 101 which is an example of an electronic device.

As illustrated in FIG. 18, the imaging apparatus 101 includes an optical system 102, an image pickup element 103 which is an example of the image pickup element 1 as described above, and a digital signal processor (DSP) 104. The DSP 104, a display apparatus 105, an operation system 106, a memory 108, a recording apparatus 109, and a power supply system 110 are connected via a bus 107, and can capture a still image and a moving image.

The optical system 102 includes one or a plurality of lenses, guides image light from a subject (incident light) to the image pickup element 103, and forms an image on a light receiving surface (sensor unit) of the image pickup element 103.

As the image pickup element 103, the image pickup element 1 of any of the above-described configuration examples is applied. Electrons are accumulated in the image pickup element 103 for a certain period according to an image formed on the light receiving surface via the optical system 102. Then, a signal corresponding to the electrons accumulated in the image pickup element 103 is supplied to the DSP 104.

The DSP 104 performs various types of signal processing on the signal from the image pickup element 103 to acquire an image, and temporarily stores data of the image in the memory 108. The image data stored in the memory 108 is recorded in the recording apparatus 109 or supplied to the display apparatus 105 to display an image. Furthermore, the operation system 106 receives various operations by the user and supplies an operation signal to each block of the imaging apparatus 101, and the power supply system 110 supplies power necessary for driving each block of the imaging apparatus 101.

In the imaging apparatus 101 configured as described above, by applying the image pickup element 1 as described above as the image pickup element 103, it is possible to deal with various pupil distances while suppressing deterioration in pixel characteristics.

### 5. Application Example

### <5-1. Application Example to Mobile Body>

The technology according to the present disclosure (present technology) can be applied to various products. For example, the technology according to the present disclosure may be realized as devices mounted on any types of mobile bodies such as automobiles, electric vehicles, hybrid electric vehicles, motorcycles, bicycles, personal mobilities, airplanes, drones, ships, robots, construction machines, or agricultural machines (tractors).

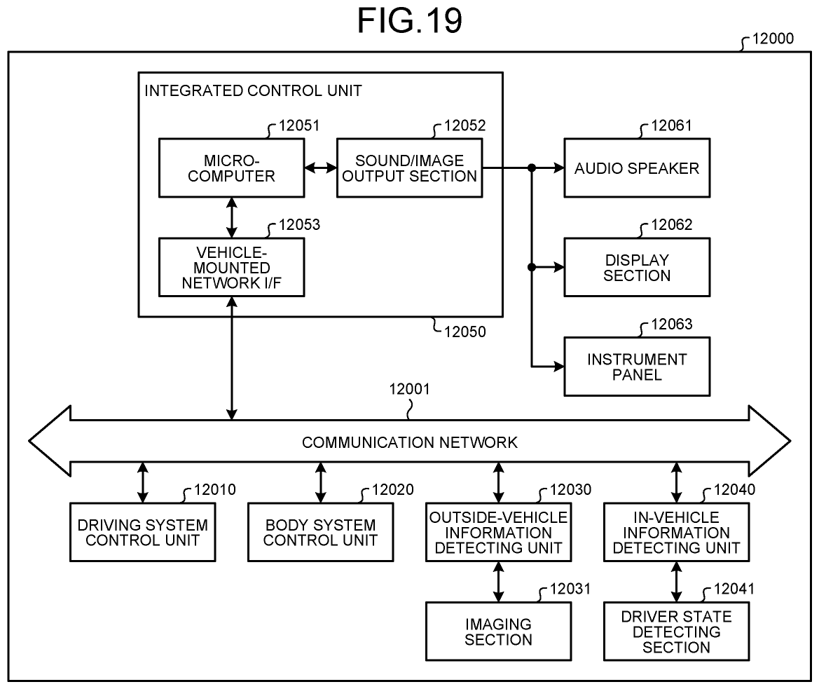

FIG. 19 is a block diagram depicting an example of schematic configuration of a vehicle control system 12000 as an example of a mobile body control system to which the technology according to an embodiment of the present disclosure can be applied.

The vehicle control system 12000 includes a plurality of electronic control units connected to each other via a communication network 12001. In the example depicted in FIG. 19, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 19, an audio speaker 12061, a display section 12062, and an instrument panel 12063 are illustrated as the output device. The display section 12062 may, for example, include at least one of an on-board display and a head-up display.

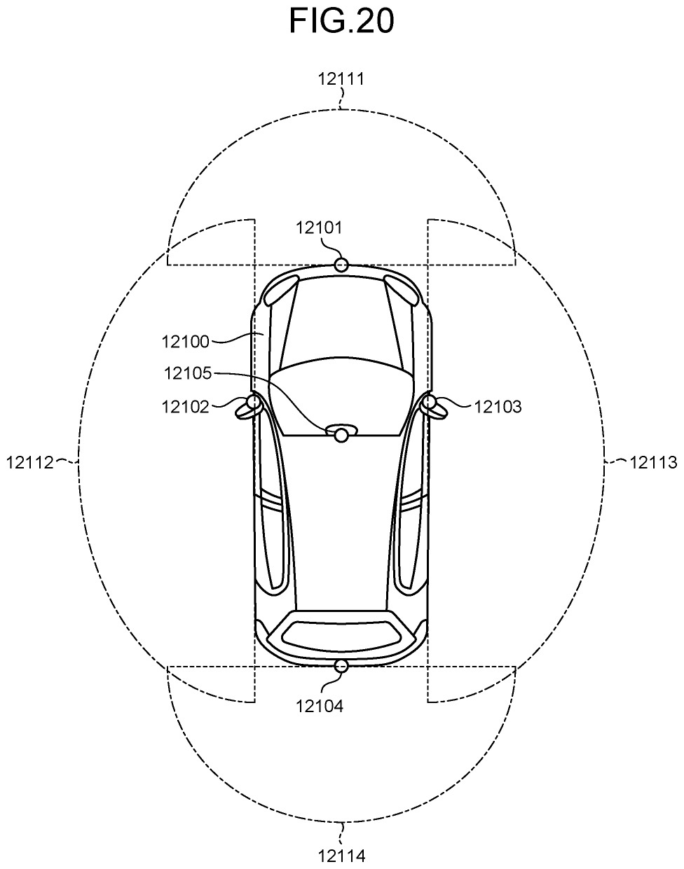

FIG. 20 is a diagram depicting an example of the installation position of the imaging section 12031.

In FIG. 20, a vehicle 12100 includes imaging sections 12101, 12102, 12103, 12104, and 12105, as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The image of the front of the vehicle obtained by the imaging sections 12101 and 12105 is used mainly to detect a preceding vehicle, a pedestrian, an obstacle, a signal, a traffic sign, a lane, or the like.

Incidentally, FIG. 20 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the above, an example of the vehicle control system to which the technology related to the present disclosure can be applied is described. The technology according to the present disclosure can be applied to, for example, the imaging section 12031 or the like within the above-described configuration. Specifically, the image pickup element 1 can be applied to the imaging section 12031. By applying the technology according to the present disclosure to the imaging section 12031, it is possible to deal with various pupil distances while suppressing deterioration in pixel characteristics.

### <5-2. Application Example to Endoscopic Surgery System>

The technology according to the present disclosure (present technology) can be applied to various products. For example, the technology according to the present disclosure may be applied to an endoscopic surgery system.

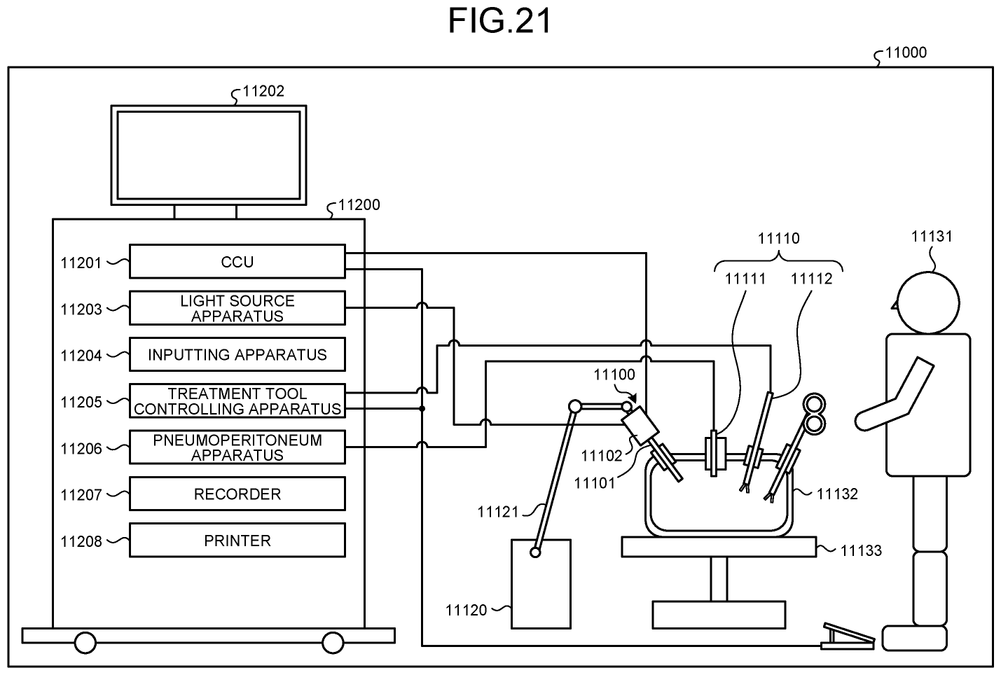

FIG. 21 is a view depicting an example of a schematic configuration of an endoscopic surgery system 11000 to which the technology according to an embodiment of the present disclosure (present technology) can be applied.

In FIG. 21, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

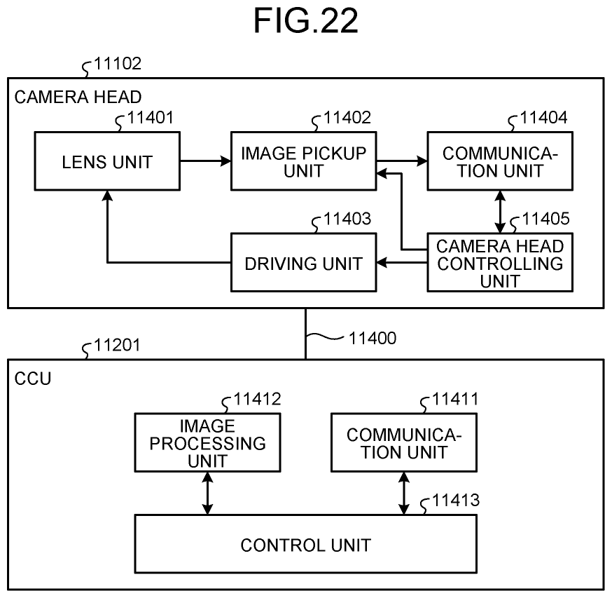

FIG. 22 is a block diagram depicting an example of a functional configuration of the camera head 11102 and the CCU 11201 depicted in FIG. 21.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the above, an example of the endoscopic surgery system 11000 to which the technology related to the present disclosure can be applied is described. The technology according to the present disclosure can be applied to, for example, the image pickup unit 11402 of the camera head 11102 within the above-described configuration. Specifically, the image pickup element 1 can be applied to the image pickup unit 11402. By applying the technology according to the present disclosure to the image pickup unit 11402, it is possible to deal with various pupil distances while suppressing deterioration in pixel characteristics.

Note that, here, the endoscopic surgery system 11000 has been described as an example, but the technology according to the present disclosure may be applied to, for example, a microscopic surgery system or the like.

### 6. Appendix

Note that the present technology can also have the following configurations.

(1)

An image pickup element, comprising
a pixel portion in which a plurality of pixels is arrayed in a matrix, wherein
the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member,
the optical member of a first pixel among the plurality of pixels is arranged to be shifted in the planar direction by a first shift amount with respect to the plurality of photoelectric conversion elements of the first pixel, and
the optical member of a second pixel different from the first pixel among the plurality of pixels is arranged to be shifted in the planar direction by a second shift amount different from the first shift amount with respect to the plurality of photoelectric conversion elements of the second pixel.
   (2)

The image pickup element according to (1), wherein
the optical member is an inner lens.
   (3)

The image pickup element according to (2), wherein
a shape of the inner lens is different from a shape of the lens.
   (4)

The image pickup element according to (2) or (3), wherein
a size of the inner lens is different from a size of the lens.
   (5)

The image pickup element according to (1), wherein
the optical member is a light shielding unit having a shape extending toward the light incident side.
   (6)

The image pickup element according to (5), wherein
the light shielding unit is formed to extend along a boundary of the plurality of photoelectric conversion elements in the planar direction.
   (7)

The image pickup element according to any one of (1) to (6), wherein
the first shift amount is a shift amount corresponding to a distance between the optical member of the first pixel and an optical axis of the pixel portion, and
the second shift amount is a shift amount corresponding to a distance between the optical member of the second pixel and an optical axis of the pixel portion.
   (8)

The image pickup element according to any one of (1) to (7), wherein
a first shift direction of the optical member of the first pixel is different from a second shift direction of the optical member of the second pixel.
   (9)

The image pickup element according to (8), wherein
the first shift direction is a direction toward the inside of the pixel portion in the planar direction, and
the second shift direction is a direction toward the outside of the pixel portion in the planar direction.
   (10)

The image pickup element according to any one of (1) to (9), wherein
a plurality of the first pixels and a plurality of the second pixels are provided, and the plurality of the first pixels and the plurality of the second pixels are alternately arranged.
   (11)

The image pickup element according to (10), wherein
the plurality of the first pixels and the plurality of the second pixels are alternately arranged in a row direction.
   (12)

The image pickup element according to (10), wherein
the plurality of the first pixels and the plurality of the second pixels are alternately arranged in a row direction and a column direction.
   (13)

The image pickup element according to any one of (1) to (9), wherein
a plurality of the first pixels and a plurality of the second pixels are provided, and
the plurality of the first pixels and the plurality of the second pixels are arranged at predetermined specific positions.
   (14)

The image pickup element according to any one of (1) to (13), wherein
the first pixels and the second pixels include color filters of different colors that transmit light of different wavelength bands, and
the first shift amount and the second shift amount are different according to the color filters of different colors.
   (15)

The image pickup element according to any one of (1) to (13), wherein
the first pixels and the second pixels include color filters of the same color that transmit light of the same wavelength band.
   (16)

The image pickup element according to any one of (1) to (15), wherein
the pixel portion includes, as the plurality of pixels, an imaging pixel prioritizing generation of an imaging signal and a parallax pixel prioritizing generation of a parallax signal, and
the first pixels and the second pixels are parallax pixels.
   (17)

The image pickup element according to (16), wherein
a shape of the optical member of the imaging pixel is different from a shape of the optical member of the parallax pixel.
   (18)

The image pickup element according to (16) or (17), wherein
a size of the optical member of the imaging pixel is different from a size of the optical member of the parallax pixel.
   (19)

The image pickup element according to (18), wherein
a size of the optical member of the imaging pixel is larger than a size of the optical member of the parallax pixel.
   (20)

An electronic device, comprising
an image pickup element, wherein
the image pickup element includes
a pixel portion in which a plurality of pixels is arrayed in a matrix,
the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member,
the optical member of a first pixel among the plurality of pixels is arranged to be shifted in the planar direction by a first shift amount with respect to the plurality of photoelectric conversion elements of the first pixel, and
the optical member of a second pixel different from the first pixel among the plurality of pixels is arranged to be shifted in the planar direction by a second shift amount different from the first shift amount with respect to the plurality of photoelectric conversion elements of the second pixel.
   (21)

An imaging apparatus comprising the image pickup element according to any one of (1) to (19).

(22)

An electronic device comprising the image pickup element according to any one of (1) to (19).

### REFERENCE SIGNS LIST

1 IMAGE PICKUP ELEMENT
2 PIXEL
3 PIXEL PORTION
4 VERTICAL DRIVE CIRCUIT
5 COLUMN SIGNAL PROCESSING CIRCUIT
6 HORIZONTAL DRIVE CIRCUIT
7 OUTPUT CIRCUIT
8 CONTROL CIRCUIT
9A PIXEL DRIVE LINE
9B VERTICAL SIGNAL LINE
10 HORIZONTAL SIGNAL LINE
11 SEMICONDUCTOR SUBSTRATE
12 PERIPHERAL CIRCUIT UNIT
13 INPUT/OUTPUT TERMINAL
21 PHOTOELECTRIC CONVERSION ELEMENT
22 INSULATING LAYER
23 FIRST LENS
24 FLATTENING LAYER
25 SECOND LENS
26 LIGHT SHIELDING WALL
26a FIRST LIGHT SHIELDING WALL
26b SECOND LIGHT SHIELDING WALL
27 COLOR FILTER
31 LIGHT SHIELDING UNIT
101 IMAGING APPARATUS
102 OPTICAL SYSTEM
103 IMAGE PICKUP ELEMENT
104 DSP
105 DISPLAY APPARATUS
106 OPERATION SYSTEM
107 BUS
108 MEMORY
109 RECORDING APPARATUS
110 POWER SUPPLY SYSTEM

1. An image pickup element, comprising
a pixel portion in which a plurality of pixels is arrayed in a matrix, wherein
the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member,
the optical member of a first pixel among the plurality of pixels is arranged to be shifted in the planar direction by a first shift amount with respect to the plurality of photoelectric conversion elements of the first pixel, and
the optical member of a second pixel different from the first pixel among the plurality of pixels is arranged to be shifted in the planar direction by a second shift amount different from the first shift amount with respect to the plurality of photoelectric conversion elements of the second pixel.

2. The image pickup element according to claim 1, wherein
the optical member is an inner lens.

3. The image pickup element according to claim 2, wherein
a shape of the inner lens is different from a shape of the lens.

4. The image pickup element according to claim 2, wherein
a size of the inner lens is different from a size of the lens.

5. The image pickup element according to claim 1, wherein
the optical member is a light shielding unit having a shape extending toward the light incident side.

6. The image pickup element according to claim 5, wherein
the light shielding unit is formed to extend along a boundary of the plurality of photoelectric conversion elements in the planar direction.

7. The image pickup element according to claim 1, wherein
the first shift amount is a shift amount corresponding to a distance between the optical member of the first pixel and an optical axis of the pixel portion, and
the second shift amount is a shift amount corresponding to a distance between the optical member of the second pixel and an optical axis of the pixel portion.

8. The image pickup element according to claim 1, wherein
a first shift direction of the optical member of the first pixel is different from a second shift direction of the optical member of the second pixel.

9. The image pickup element according to claim 8, wherein
the first shift direction is a direction toward the inside of the pixel portion in the planar direction, and
the second shift direction is a direction toward the outside of the pixel portion in the planar direction.

10. The image pickup element according to claim 1, wherein
a plurality of the first pixels and a plurality of the second pixels are provided, and
the plurality of the first pixels and the plurality of the second pixels are alternately arranged.

11. The image pickup element according to claim 10, wherein
the plurality of the first pixels and the plurality of the second pixels are alternately arranged in a row direction.

12. The image pickup element according to claim 10, wherein
the plurality of the first pixels and the plurality of the second pixels are alternately arranged in a row direction and a column direction.

13. The image pickup element according to claim 1, wherein
a plurality of the first pixels and a plurality of the second pixels are provided, and
the plurality of the first pixels and the plurality of the second pixels are arranged at predetermined specific positions.

14. The image pickup element according to claim 1, wherein
the first pixels and the second pixels include color filters of different colors that transmit light of different wavelength bands, and
the first shift amount and the second shift amount are different according to the color filters of different colors.

15. The image pickup element according to claim 1, wherein
the first pixels and the second pixels include color filters of the same color that transmit light of the same wavelength band.

16. The image pickup element according to claim 1, wherein
the pixel portion includes, as the plurality of pixels, an imaging pixel prioritizing generation of an imaging signal and a parallax pixel prioritizing generation of a parallax signal, and
the first pixels and the second pixels are parallax pixels.

17. The image pickup element according to claim 16, wherein
a shape of the optical member of the imaging pixel is different from a shape of the optical member of the parallax pixel.

18. The image pickup element according to claim 16, wherein
a size of the optical member of the imaging pixel is different from a size of the optical member of the parallax pixel.

19. The image pickup element according to claim 18, wherein
a size of the optical member of the imaging pixel is larger than a size of the optical member of the parallax pixel.

20. An electronic device, comprising
an image pickup element, wherein
the image pickup element includes
a pixel portion in which a plurality of pixels is arrayed in a matrix,
the plurality of pixels each includes a plurality of photoelectric conversion elements arranged in a planar direction of the pixel portion, an optical member positioned on a light incident side with respect to the plurality of photoelectric conversion elements and refracting light, and a lens positioned on the light incident side with respect to the optical member,
the optical member of a first pixel among the plurality of pixels is arranged to be shifted in the planar direction by a first shift amount with respect to the plurality of photoelectric conversion elements of the first pixel, and
the optical member of a second pixel different from the first pixel among the plurality of pixels is arranged to be shifted in the planar direction by a second shift amount different from the first shift amount with respect to the plurality of photoelectric conversion elements of the second pixel.
